(19) United States
(12) Patent Application Publication
(10) Pub. No.: US 2011/0183504 A1
(43) Pub. Date: Jul. 28, 2011

(54) METHODS OF FORMING A DUAL-DOPED EMITTER ON A SUBSTRATE WITH AN INLINE DIFFUSION APPARATUS

(75) Inventors: Giuseppe Scardera, Sunnyvale, CA (US); Malcolm Abbott, San Jose, CA (US); Dmitry Poplavskyy, San Jose, CA (US); Sunil Shah, Union City, CA (US)

(73) Assignee: Innovalight, Inc.

(21) Appl. No.: 12/692,878

(22) Filed: Jan. 25, 2010

(51) Int. Cl. H01L 21/225

(52) U.S. Cl. 438/558; 257/E21.144

(57) ABSTRACT

A method of forming a multi-doped junction is disclosed. The method includes providing a substrate doped with boron atoms, the substrate comprising a front substrate surface. The method also includes depositing an ink on the front substrate surface in an ink pattern, the ink comprising a set of nanoparticles and a set of solvents; and heating the substrate in a baking ambient at a baking temperature and for a baking time period wherein a densified ink layer is formed. The method further includes exposing the substrate to a phosphorous dopant source at a drive-in temperature and for a drive-in time period.

### FIELD OF DISCLOSURE

This disclosure relates in general to p-n junctions and in particular to methods of forming a dual-doped emitter on a substrate with an inline diffusion apparatus.

### BACKGROUND

A solar cell converts solar energy directly to DC electric energy. Generally configured as a photodiode, a solar cell permits light to penetrate into the vicinity of metal contacts such that a generated charge carrier (electrons or holes (a lack of electrons)) may be extracted as current. And like most other diodes, photodiodes are formed by combining p-type and n-type semiconductors to form a junction.

Electrons on the p-type side of the junction within the electric field (or built-in potential) may then be attracted to the n-type region (usually doped with phosphorous) and repelled from the p-type region (usually doped with boron), whereas holes within the electric field on the n-type side of the junction may then be attracted to the p-type region and repelled from the n-type region. Generally, the n-type region and/or the p-type region can each respectively be comprised of varying levels of relative dopant concentration, often shown as n−, n+, n++, p−, p+, p++, etc. The built-in potential and thus magnitude of electric field generally depend on the level of doping between two adjacent layers.

Substantially affecting solar cell performance, carrier lifetime (recombination lifetime) is defined as the average time it takes an excess minority carrier (non-dominant current carrier in a semiconductor region) to recombine and thus become unavailable to conduct an electrical current. Likewise, diffusion length is the average distance that a charge carrier travels before it recombines. In general, although increasing dopant concentration improves conductivity, it also tends to increase recombination. Consequently, the shorter the recombination lifetime or recombination length, the closer the metal region must be to where the charge carrier was generated.

Most solar cells are generally formed on a silicon substrate doped with a first dopant (commonly boron) forming an absorber region, upon which a second counter dopant (commonly phosphorous), is diffused forming the emitter region, in order to complete the p-n junction. After the addition of passivation and antireflection coatings, metal contacts (fingers and busbar on the emitter and pads on the back of the absorber) may be added in order to extract generated charge. Emitter dopant concentration, in particular, must be optimized for both carrier collection and for contact with the metal electrodes.

In general, a low concentration of (substitutional) dopant atoms within an emitter region will result in both low recombination (thus higher solar cell efficiencies), and poor electrical contact to metal electrodes. Conversely, a high concentration of (substitutional) dopant atoms will result in both high recombination (thus reducing solar cell efficiency), and low resistance ohmic contacts to metal electrodes. Often, in order to reduce manufacturing costs, a single dopant diffusion is generally used to form an emitter, with a doping concentration selected as a compromise between low recombination and low resistance ohmic contact. Consequently, potential solar cell efficiency (the percentage of sunlight that is converted to electricity) is limited.

One solution is the use of a dual-doped or selective-emitter. A selective emitter uses a first lightly doped region optimized for low recombination, and a second heavily doped region (of the same dopant type) optimized for low resistance ohmic metal contact. However, a selective-emitter configuration may be difficult to achieve in a one-step diffusion process and may involve several masking steps, consequently increasing manufacturing costs. In addition, since there are generally no visual boundaries between high doped and low doped emitter regions, the alignment of a metal contact onto a previously deposited highly doped region may be difficult.

In view of the foregoing, there is a desire to provide methods of forming a dual-doped emitter on a substrate with an inline diffusion apparatus.

### SUMMARY

The invention relates, in one embodiment, to a method of forming a multi-doped junction. The method includes providing a substrate doped with boron atoms, the substrate comprising a front substrate surface. The method also includes depositing an ink on the front substrate surface in an ink pattern, the ink comprising one or more nanoparticles and one or more solvents; and heating the substrate for a time period wherein a densified ink layer is formed. The method further optionally includes exposing the substrate to a phosphorous dopant source at a drive-in temperature and for a drive-in time period.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a simplified diagram of a solar cell with a selective emitter and aluminum BSF;

FIG. 2 compares the sheet resistance of four sets of silicon substrates configured with masking ink patterns of various thicknesses and processed at a temperature of about 865° C., in accordance with the invention;

FIGS. 3A-B compare the sheet resistance for four sets of silicon substrates configured with masking ink patterns of various thicknesses and processed at a temperature of about 880° C., in accordance with the invention;

FIG. 4 shows a simplified process for the manufacture of a substrate with a masking ink pattern, in accordance with the invention;

FIG. 5 shows a simplified diagram of FTIR (Fourier Transform Infra-Red) spectra for a double-sided polished mono-crystalline silicon substrate configured with a doping ink pattern with a thickness of about 260 nm, in accordance with the invention;

FIG. 6 compares the sheet resistance for four sets of silicon substrates configured with 260 nm doping ink patterns and processed at various temperatures, in accordance with the invention;

FIG. 7 compares the sheet resistance for two sets of silicon substrates, each processed in a different diffusion ambient with a 3000 nm doping ink pattern and at 800° C., in accordance with the invention;

FIG. 8 shows a set of polynomial fitted curves along with one simplified extrapolation curve for data from FIG. 6, in accordance with the invention;

FIG. 9 shows a simplified process for the manufacture of a substrate with a doping ink pattern, in accordance with the invention; and

FIG. 10 shows a simplified diagram of an inline diffusion apparatus, in accordance with the invention.

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

As previously described, forming multi-doped junctions on a substrate, such as for a solar cell, tends to be problematic since multiple separate diffusions and patterning steps are often required, consequently increasing manufacturing costs.

In an advantageous manner, a silicon nanoparticle fluid (e.g., ink, paste, etc.) may be deposited in an (ink) pattern on a silicon substrate surface, such that both a set of lightly doped regions and a set of heavily doped regions (such as for a selective emitter) are formed in-situ in an inline diffusion process. In one configuration, the set of heavily doped regions are formed under surface areas not covered with a masking ink pattern. In an alternate configuration, the set of heavily doped regions are formed under surface areas covered with a doping ink pattern.

For example, a common method of forming a single doped emitter on a multi-crystalline or mono-crystalline solar cell involves the transportation of the substrate on a conveyer belt through a mist consisting of H₃PO₄ mixed with an alcohol (e.g. ethanol, etc.) or water followed by a temperature of about 35° C. and further followed by a temperature of about 850° C. to about 950° C. Phosphorus atoms are driven into the silicon substrate via the following reactions:

2H₃PO₄₍ₗ₎ )→P₂O₅₍ₗ₎ +3H₂O₍ₗ₎ [Equation 1A]

2P₂O₅₍ₗ₎₊5Si₍ₛ₎→5SiO₂₍ₛ₎₊4P₍ₛ₎ [Equation 1B]

Si+O₂→SiO₂ [Equation 2]

The first step involves the dehydration of phosphoric acid which produces phosphoric pentoxide (P₂O₅) on the silicon surface which in turn acts as the phosphorus source. P₂O₅ in turn reacts with the silicon substrate to form SiO₂, and free P atoms. Since the reduction of P₂O₅ generally occurs in oxygen containing ambient, the silicon surface will simultaneously undergo a certain amount of oxidation.

One method of depositing the layer of nanoparticles onto the silicon substrate surface is the deposition through the use of a fluid, such as a colloidal dispersion. Generally, colloidal dispersions of Group IV nanoparticles are possible because the interaction of the particle surface with the solvent is strong enough to overcome differences in density, which usually result in a material either sinking or floating in a liquid. That is, smaller nanoparticles disperse more easily than larger nanoparticles. Commonly, particle loadings for an ink may be around about 3% wt. In contrast, if the particle loading substantially increases above about 10% wt., the colloidal dispersion thickens into a paste.

In general, the Group IV nanoparticles are transferred into the colloidal dispersion or paste under a vacuum, or an inert substantially oxygen-free environment. In addition, the use of particle dispersal methods and equipment such as sonication, high shear mixers, and high pressure/high shear homogenizers may be used to facilitate dispersion of the nanoparticles in a selected solvent or mixture of solvents.

Examples of solvents include alcohols, aldehydes, ketones, carboxylic acids, esters, amines, organosiloxanes, halogenated hydrocarbons, and other hydrocarbon solvents. In addition, the solvents may be mixed in order to optimize physical characteristics such as viscosity, density, polarity, etc.

In addition, in order to better disperse the Group IV nanoparticles in the colloidal dispersion, nanoparticle capping groups may be formed with the addition of organic compounds, such as alcohols, aldehydes, ketones, carboxylic acids, esters, and amines, as well as organosiloxanes. Alternatively, capping groups may be added in-situ by the addition of gases into the plasma chamber. These capping groups may be subsequently removed during the sintering process, or in a lower temperature pre-heat just before the sintering process.

For example, bulky capping agents suitable for use in the preparation of capped Group IV semiconductor nanoparticles include C4-C8 branched alcohols, cyclic alcohols, aldehydes, and ketones, such as tertiary-butanol, isobutanol, cyclohexanol, methyl-cyclohexanol, butanal, isobutanol, cyclohexanone, and organosiloxanes, such as methoxy(tris(trimethylsilyl)silane)(MTTMSS), tris(trimethylsilyl)silane (TTMSS), decamethyltetrasiloxane (DMTS), and trimethylmethoxysilane (TMOS).

Once formulated, the colloidal dispersion may be applied to a substrate and subjected to a heat treatment in order to drive off residual solvent from the film. Examples of application methods include, but are not limited to, roll coating, slot die coating, gravure printing, flexographic drum printing, and inkjet printing methods, etc.

Additionally, various configurations of doped Group IV nanoparticle colloidal dispersions can be formulated by the selective blending of doped, undoped, and/or differently doped Group IV nanoparticles. For example, various formulations of blended Group IV nanoparticle colloidal dispersions can be prepared in which the dopant level for a specific layer of a junction is formulated by blending doped and undoped Group IV nanoparticles to achieve the requirements for that layer.

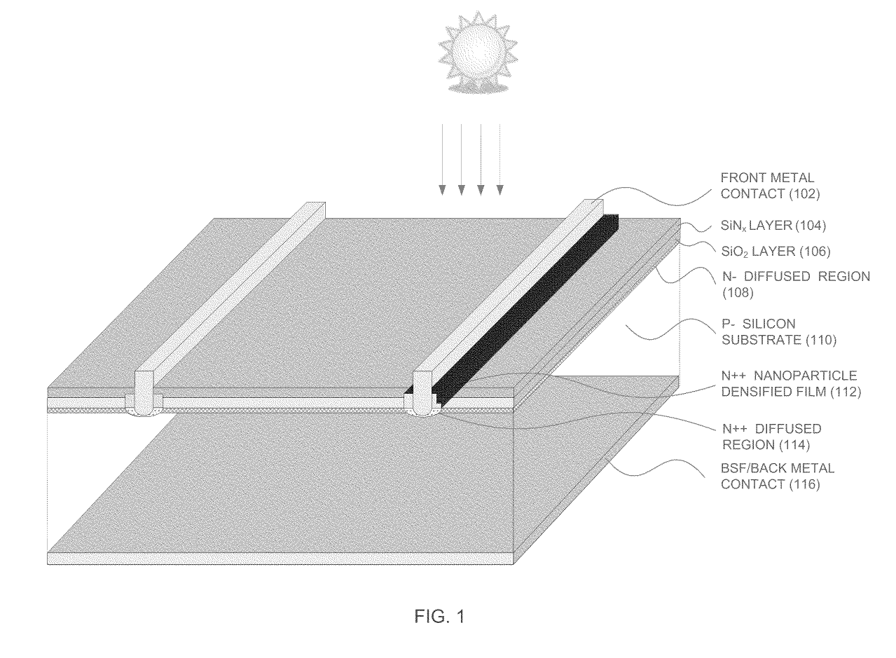

Referring now to FIG. 1, a simplified diagram of a solar cell with a selective emitter and aluminum BSF. In a common configuration, an n++diffused region 114 and n-diffused region 108 are first formed on a p-(lightly doped) silicon substrate 110. SiO₂ layer 106 is then formed on a p-(lightly doped) silicon substrate 110 in order to help passivate the front surface of silicon substrate 110.

A SiNₓ 104 layer is then formed on the front surface of SiO₂ layer 106. Like SiO₂ layer 106, SiNₓ layer 104 helps passivate the surface of silicon substrate 110, minimizing both contamination of the wafer bulk from external sources, as well as reducing minority carrier recombination at the surface of silicon substrate 110. Additionally, SiNₓ 104 layer may be optimized to reduce the reflectivity of the front surface of the solar cell, substantially improving efficiency and thus performance.

Front-metal contact 102 and back surface field (BSF)/back metal contact 116 are then generally formed on silicon substrate 110. Front-metal contact 102 is generally formed from an Ag paste comprising Ag powder (70 to 80 at %), lead borosilicate glass PbO—B₂O₃—SiO₂ (1 to 10 at %), and organic components (15 to 30 at %). BSF/back metal contact 116 is generally formed from aluminum, and is configured to create an electrical field that repels and thus minimize the impact of minority carrier rear surface recombination. In addition, Ag pads [not shown] are generally applied onto BSF/back metal contract 116 in order to facilitate soldering for interconnection into modules.

### Masking Ink Pattern

### Experiment 1

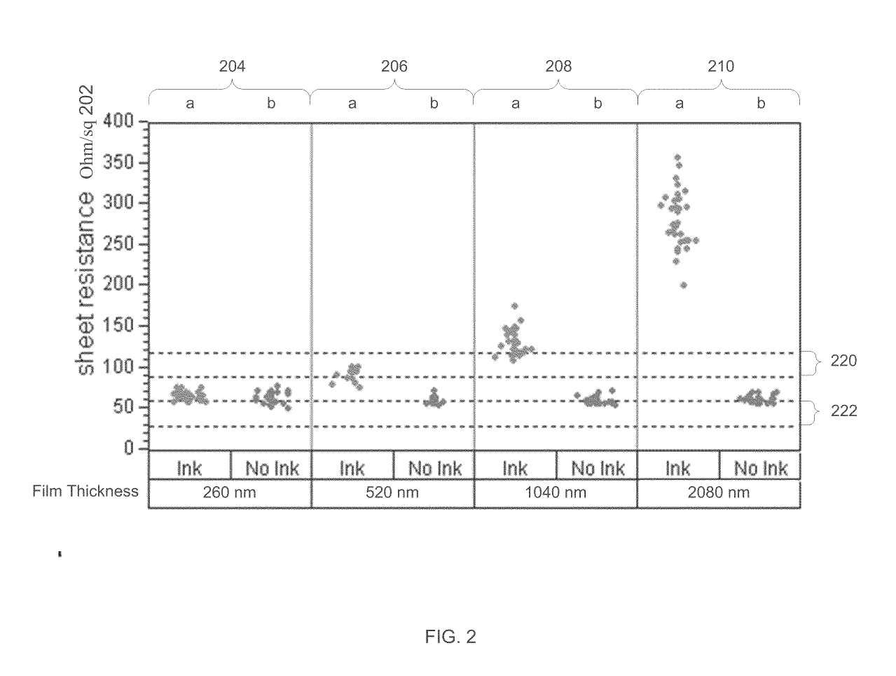

Referring now to FIG. 2, the sheet resistance of four sets of silicon substrates is compared, wherein each substrate is configured with masking ink patterns of various thicknesses and processed at a temperature of about 865° C., in accordance with the invention. That is, it is intended that areas under the ink are substantially shielded from any ambient dopant source, while the remaining substrate surface area are substantially exposed to the dopant source. In these configurations, as the thickness of the deposited ink is increased, the underlying sheet resistance also tends to increase which corresponds to a lower dopant concentration. In addition, the masking ink pattern may be intrinsic or may be doped (for example with phosphorous).

Sheet resistance 202 in Ohm/sq is shown along the vertical axis. In general for a selective emitter solar cell configuration, a first sheet resistance range 220 of between about 90 Ohm/sq to about 120 Ohm/sq (corresponding to a lightly doped region) is optimal for low charge carrier recombination in the emitter region, while a second sheet resistance range 222 of between about 30 Ohm/sq and about 60 Ohm/sq (corresponding to a heavily doped region) is optimal for good ohmic contact with a metal contact.

All substrate sets comprised of saw-damage etched p-type silicon substrates, each with a thickness of about 180 um and a resistivity of about 2 Ohm-cm. The substrates were first cleaned with piranha (a mixture of sulfuric acid (H₂SO₄) and hydrogen peroxide (H₂O₂)). This cleaning was followed by an initial DI water rinsing step, a buffered oxide etch (BOE) dip, a final DI water rinse, and a subsequent N₂ gas drying.

A set of silicon ink square patterns was then deposited on the substrate surface, and in some cases re-deposited, in order to subsequently form a set of silicon ink layers (each about 260 nm in thickness after densification), wherein silicon ink contains silicon nanoparticles with 1.4 wt % phosphorous (although the inventors believe that intrinsic silicon ink would have a substantially similar effect).

Substrates were then subjected to baking at a temperature of 600° C. in a baking ambient in a rapid thermal processing (RTP) tool for a baking time period of about 3 minutes in order to densify the film and evaporate solvent molecules. The inventors believe the baking time period may be between about 30 seconds and about 20 minutes. The inventors further believe that a baking temperature of between about 200° C. and about 600° C. is preferable, a baking temperature of between about 300° C. and about 500° C. is more preferable, and a baking temperature of about 400° C. is most preferable.

Substrate sets 204-210 were then exposed to a liquid 2.5 wt % H₃PO₄ (phosphoric acid) dopant source (ethanol dilution), followed by a dehydration step at about 35° C. for about 3 minutes and then subjected to a drive-in step on an inline belt furnace, at a drive-in temperature of about 865° C. and for a drive-in time period of about 20 minutes. The residual PSG glass layers on the substrate surface and the densified film surface were subsequently removed by a BOE cleaning step for about 5 minutes.

In substrate subset 204, configured with one densified ink layer with a thickness of about 260 nm, an average sheet resistance of 65.0 ohm/sq was measured in ink areas 204a (i.e., substrate areas underneath the deposited densified nanoparticle film), while an average sheet resistance of 64.2 ohm/sq was measured in non-ink areas 204b (i.e., on a neighboring substrate free of any deposited densified nanoparticle film). That is, the sheet resistance is low in ink areas 204a, which correspond to the emitter regions on the solar cell substrate. Consequently, the differential dopant profile between heavily doped and lightly doped regions (as reflected in sheet resistance) is not optimal for the formation of a selective emitter as previously described.

In substrate subset 210, configured with four sequentially deposited densified ink layers with a thickness of about 2080 nm, an average sheet resistance of 283.0 ohm/sq was measured in ink areas 210a, while an average sheet resistance of 61.4 ohm/sq was measured in non-ink areas 210b. That is, the sheet resistance is excessively high in ink areas 210a, which correspond to the emitter regions on the solar cell substrate. Consequently, the differential dopant profile between heavily doped and lightly doped regions (as reflected in sheet resistance) is not optimal for the formation of a selective emitter as previously described.

In contrast, substrate subsets 206 and 208 show a beneficial differential dopant profile for the formation of a selective emitter, although the resultant sheet resistance values do not fall into the ideal ranges.

In substrate subset 206, configured with two deposited densified ink layers with a thickness of about 520 nm, an average sheet resistance of 92.3 ohm/sq was measured in ink areas 206a, while an average sheet resistance of 60.6 ohm/sq was measured in non-ink areas 206b. Consequently, the differential dopant profile between heavily doped and lightly doped regions (as reflected in sheet resistance) is beneficial for the formation of a selective emitter as previously described.

Likewise, substrate subset 208 configured with three deposited densified ink layers with a thickness of about 1040 nm, an average sheet resistance of 131.9 was measured in ink areas 208a, while an average sheet resistance of 60.5 ohm/sq was measured in non-ink areas 208b. Consequently, the differential dopant profile between heavily doped and lightly doped regions (as reflected in sheet resistance) is beneficial for the formation of a selective emitter as previously described.

### Experiment 2

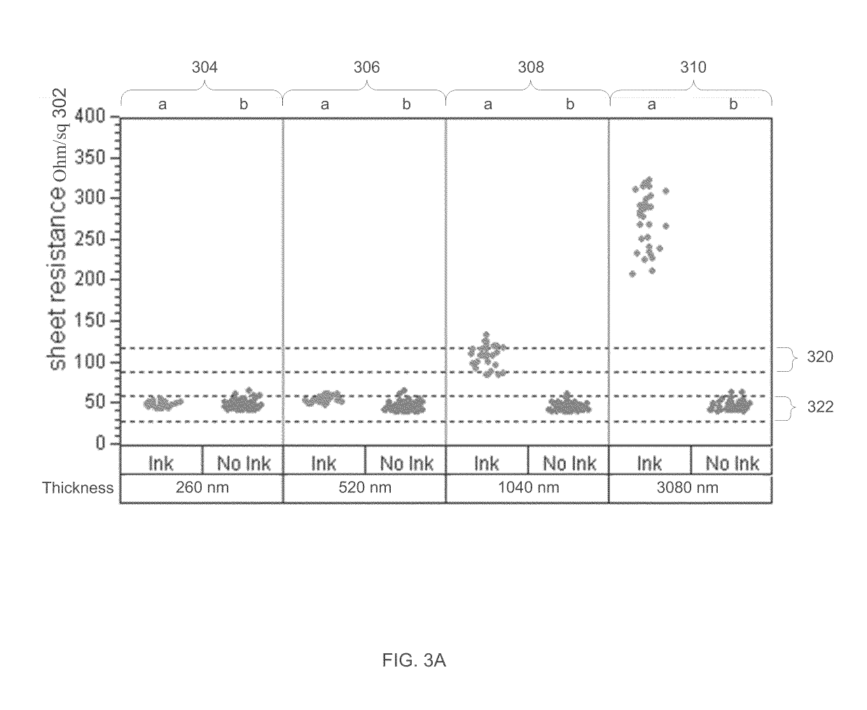

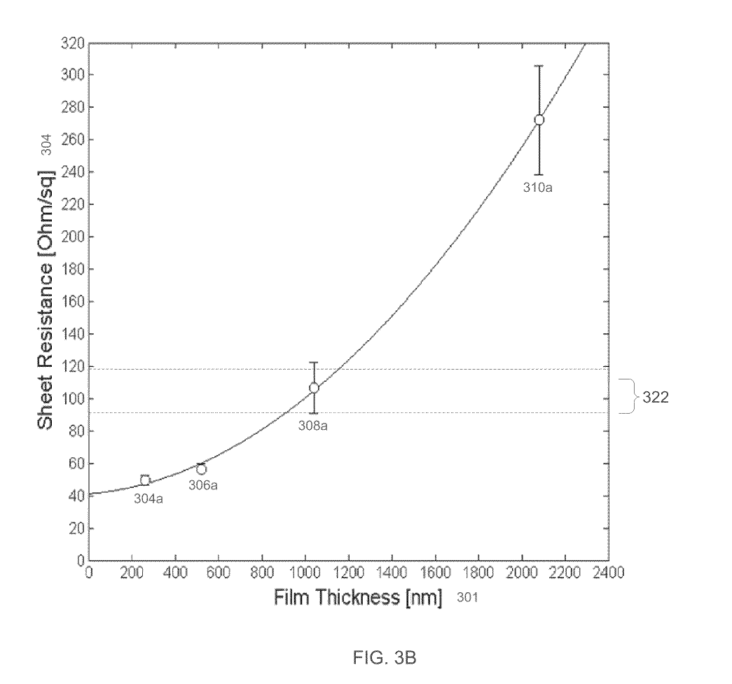

Referring now to FIGS. 3A-B, the sheet resistances for four sets of silicon substrates is compared, wherein each substrate is configured with masking ink patterns of various thicknesses and processed at a temperature of about 880° C., in accordance with the invention. That is, it is intended that areas under the ink are substantially shielded from any ambient dopant source, while the remaining substrate surface area are substantially exposed to the dopant source. In these configurations, as the thickness of the deposited ink is increased, the underlying resistivity also tends to increase which corresponds to a lower dopant concentration. In addition, the masking ink pattern may be intrinsic or may be doped (for example with phosphorous).

Referring to FIG. 3A, sheet resistance 302 in ohm/sq is shown along the vertical axis. As previously described, sheet resistance range 320 (between about 90 Ohm/sq to about 120 Ohm/sq) corresponds to a lightly doped region optimized for low recombination, while range 322 (between about 30 Ohm/sq and about 60 Ohm/sq) corresponds to a heavily doped region optimized for good ohmic contact.

All substrate sets comprised of saw-damage etched p-type silicon substrates, each with a thickness of about 180 um and a resistivity of about 2 Ohm-cm. The substrates were first cleaned with piranha (a mixture of sulfuric acid (H₂SO₄) and hydrogen peroxide (H₂O₂)). This cleaning was followed by an initial DI water rinsing step, a buffered oxide etch (BOE) dip, a final DI water rinse, and a subsequent N₂ gas drying.

A set of silicon ink square patterns was then deposited on the substrate surface, and in some cases re-deposited, in order to subsequently form a set of silicon ink layers (each about 260 nm in thickness after densification), wherein silicon ink contains silicon nanoparticles with 1.4 wt % phosphorous (although the inventors believe that intrinsic silicon ink would have a substantially similar effect).

Substrates were then subjected to baking at a temperature of 600° C. in a baking ambient in a rapid thermal processing (RTP) tool for a baking time period of about 3 minutes in order to densify the film and evaporate solvent molecules.

The inventors believe the baking time period may be between about 30 seconds and about 20 minutes. The inventors further believe that a baking temperature of between about 200° C. and about 600° C. is preferable, a baking temperature of between about 300° C. and about 500° C. is more preferable, and a baking temperature of about 400° C. is most preferable.

Substrate sets 304-310 were then exposed to a liquid 2.5 wt % H₃PO₄ dopant source (ethanol dilution), followed by a dehydration step at about 35° C. for about 3 minutes, and then subjected to a drive-in step on an inline belt furnace, at a drive-in temperature of about 880° C. and for a drive-in time of about 20 minutes. The residual PSG glass layers on the substrate surface and the densified film surface were subsequently removed by a BOE cleaning step for about 5 minutes.

In substrate subset 304, configured with one densified ink layer with a thickness of about 260 nm, an average sheet resistance of 49.5 ohm/sq was measured in ink areas 304a (i.e., substrate areas underneath the deposited densified nanoparticle film), while an average sheet resistance of 48.4 ohm/sq was measured in non-ink areas 304b (i.e., on a neighboring substrate free of any deposited densified nanoparticle film). That is, the sheet resistance is low in ink areas 304a, which correspond to the emitter regions on the solar cell substrate. Consequently, the differential dopant profile between heavily doped and lightly doped regions (as reflected in sheet resistance) is not optimal for the formation of a selective emitter as previously described.

In substrate subset 306, configured with two deposited densified ink layers with a thickness of about 520 nm, an average sheet resistance of 55.9 ohm/sq was measured in ink areas 306a, while an average sheet resistance of 45.3 was measured in non-ink areas 306b. That is, the sheet resistance is excessively low in ink areas 306a, which correspond to the emitter regions on the solar cell substrate. Consequently, the differential dopant profile between heavily doped and lightly doped regions (as reflected in sheet resistance) is not optimal for the formation of a selective emitter as previously described.

In contrast, substrate subset 308 shows an optimal differential dopant profile for the formation of a selective emitter. In substrate subset 308, configured with three deposited densified ink layers with a thickness of about 1040 nm, an average sheet resistance of 108.9 ohm/sq was measured in ink areas 308a, while an average sheet resistance of 45.3 ohm/sq was measured in non-ink areas 308b. Consequently, the differential dopant profile between heavily doped and lightly doped regions (as reflected in sheet resistance) is optimal for the formation of a selective emitter as previously described.

In substrate subset 310, configured with four sequentially deposited densified ink layers with a thickness of about 3080 nm, an average sheet resistance of 272.1 ohm/sq was measured in ink areas 310a, while an average sheet resistance of 46.9 ohm/sq was measured in non-ink areas 310b. That is, the sheet resistance is excessively high in ink areas 310a, which correspond to the emitter regions on the solar cell substrate. Consequently, the differential dopant profile between heavily doped and lightly doped regions (as reflected in sheet resistance) is not optimal for the formation of a selective emitter as previously described.

Referring now to FIG. 3B, compares sheet resistance to film thickness for the four sets of silicon substrates of FIG. 3A, in accordance with the invention. Film thickness in nm is shown along the horizontal axis, while sheet resistance 302 in Ohm/sq is shown along the vertical axis. In general, as film thickness increases, sheet resistance increases. As can be seen, for substrate subset 308a, a film thickness of about 1040 nm corresponds to a sheet resistance of between about 90 Ohm/sq to about 120 Ohm/sq, which corresponds to an optimal dopant concentration for the lightly doped region of a selective emitter. Substrate subsets 304a-306a with thinner film thicknesses show a sheet resistance less than 90 Ohm/sq, while substrate subset 310a with a thicker film thickness shows a sheet resistance of more than 120 Ohm/sq.

Consequently, the inventors believe that a drive-in temperature of between about 800° C. and about 950° C. and a drive-in time period of between about 10 minutes and about 60 minutes is preferable, a drive-in temperature of between about 850° C. and about 900° C. and a drive-in time period of between about 15 minutes and about 30 minutes is more preferable, and a drive-in temperature of about 880° C. and a drive-in time period of about 20 minutes is most preferable.

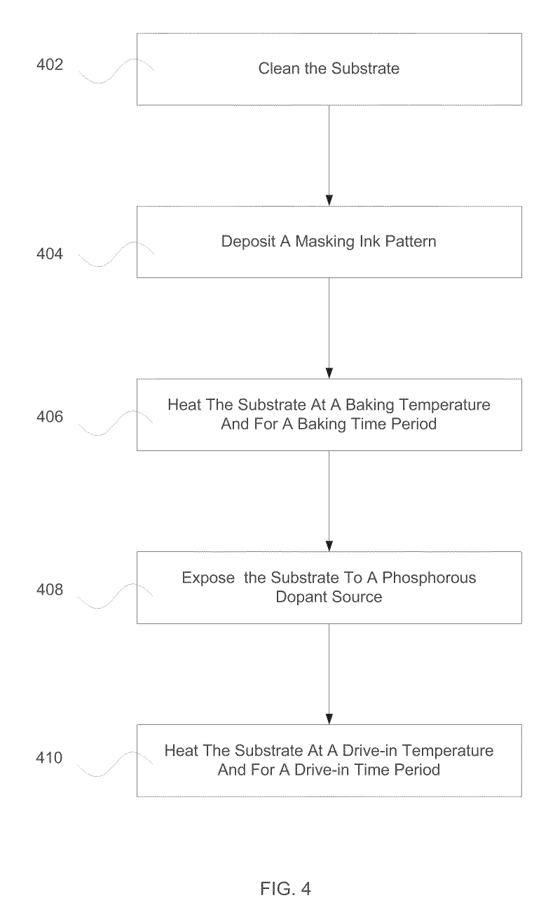

Referring now to FIG. 4, a simplified process is shown for the manufacture of a substrate with a masking ink pattern, in accordance with the invention.

Initially at step 402, the substrate is cleaned by set of substrate cleaning solutions. For example, in a common configuration, the substrate may be initially cleaned with piranha (a mixture of sulfuric acid (H₂SO₄) and hydrogen peroxide (H₂O₂)), followed by an initial DI water rinsing step, a buffered oxide etch (BOE) dip, a final DI water rinse, and subsequent drying in an N₂ gas.

At step 404, a masking ink pattern is then deposited on the substrate surface. For a masking effect, a deposited ink thickness (after densification) between about 50 nm and about 3000 nm is preferable, between about 500 nm and about 2000 nm is more preferable, and 1000 nm is most preferable. The inventors believe that the masking ink pattern may be intrinsic or may be doped (for example with phosphorous).

At step 406, the substrate is heated at a baking temperature between about 200° C. and about 600° C., more preferably between about 300° C. and about 500° C., and most preferably 400° C., and for a first time period between about 30 seconds and about 20 minutes.

At step 408, the substrate is exposed to a phosphorous dopant source. In general and as previously described, areas under the ink will be substantially shielded from any ambient dopant source, while the remaining substrate surface area is substantially exposed to the dopant source.

At step 410, the substrate is heated at a drive-in temperature between about 800° C. and about 950° C., more preferably between about 850° C. and about 900° C., and most preferably 880° C., and for a drive-in period between about 10 minutes and about 60 minutes, more preferably between about 15 minutes and 30 minutes, and most preferably 20 minutes.

### Doping Ink Pattern

### Experiment 3

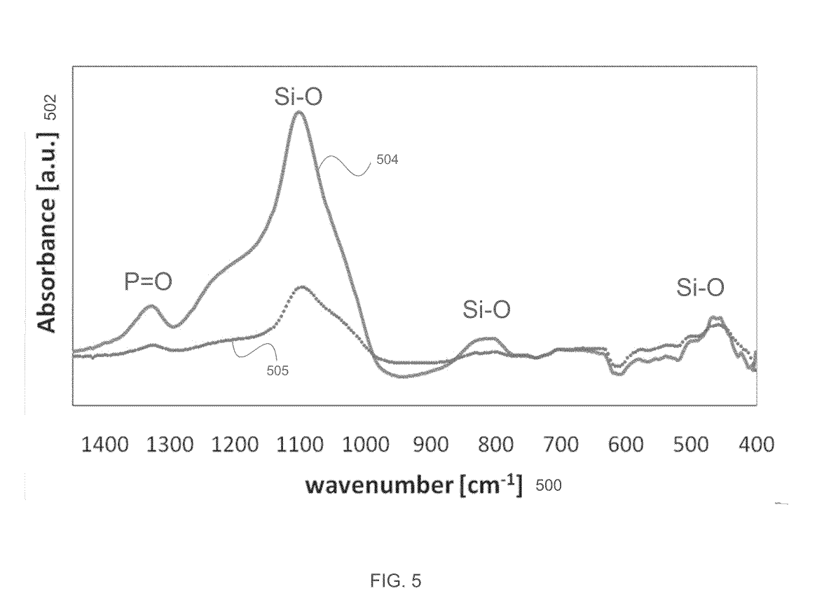

Referring now to FIG. 5, a simplified diagram of FTIR (Fourier Transform Infra-Red) spectra for a double-sided polished mono-crystalline silicon substrate, with a resistivity of about 10000 Ohm-cm, upon which a fluid containing silicon nanoparticles was deposited, in accordance with the invention. The first spectrum 505 shows the absorbance of substrate areas without deposited ink, while the second spectrum 504 shows the absorbance of substrate areas with deposited ink. Unlike the previous two experiments, it is intended that areas under the ink are substantially doped from the ambient dopant source, while the remaining substrate surface area are minimally doped from the ambient dopant source.

In general, Fourier transform spectroscopy is a measurement technique whereby spectra are collected based on measurements of the temporal coherence of a radiative source, using time-domain measurements of the electromagnetic radiation or other type of radiation 500 (shown as wave number on the horizontal axis). At certain resonant frequencies characteristic of the chemical bonding within a specific sample, the radiation 502 will be absorbed (shown as absorbance A.U. on the vertical axis) resulting in a series of peaks in the spectrum, which can then be used to identify the chemical bonding within samples. The radiation absorption is proportional the number of bonds absorbing at a given frequency.

Here, patterned patches of silicon fluid were deposited onto a polished mono-crystalline silicon substrate such that only portions of the surface are covered. The substrate was heated to a baking temperature of about 600° C. for a baking time period of about 3 minutes in an inert ambient in a rapid thermal processing (RTP) tool in order to bake off solvents in the fluid and form a densified film. The substrate was then exposed to a liquid 2.5% wt H₃PO₄ dopant source (ethanol dilution), followed by a dehydration step at about 35° C. for about 3 minutes and then subjected to an inline belt furnace, at a drive-in temperature of about 880° C. and at a drive-in temperature of about 20 minutes.

First spectrum 505 and second spectrum 504 show peaks in the range of 1330 cm⁻¹ that is characteristic of P═O (phosphorous oxygen double bonding) and around 450 cm⁻¹, 800 cm⁻¹, and 1100 cm⁻¹ that are characteristic of Si—O (silicon oxygen single bonding), all typical of deposited PSG films. The absorbance of the second (ink) spectrum 504 is substantially greater than the absorbance of the first (non-ink) spectrum 505, indicating that there is significantly more PSG embedded in the ink areas than on the non-ink areas. The evidence of significantly more PSG embedded in the ink areas as compared to the non ink areas is consistent with the larger silicon surface area provided by the ink layer for PSG deposition compared with the silicon substrate surface.

While not wishing to be bound by theory, the inventors believe that the substantially larger surface areas of deposited nanoparticles (in comparison to the relative smaller surface area of the underlying substrate) allow a larger volume of surface PSG to be formed, which in turn, allows for a larger amount of phosphorus to be driven in. Consequently, corresponding substrate areas beneath the deposited ink are exposed to a pseudo-unlimited dopant source compared to a limited dopant source in those areas not beneath the ink.

Experiment 4

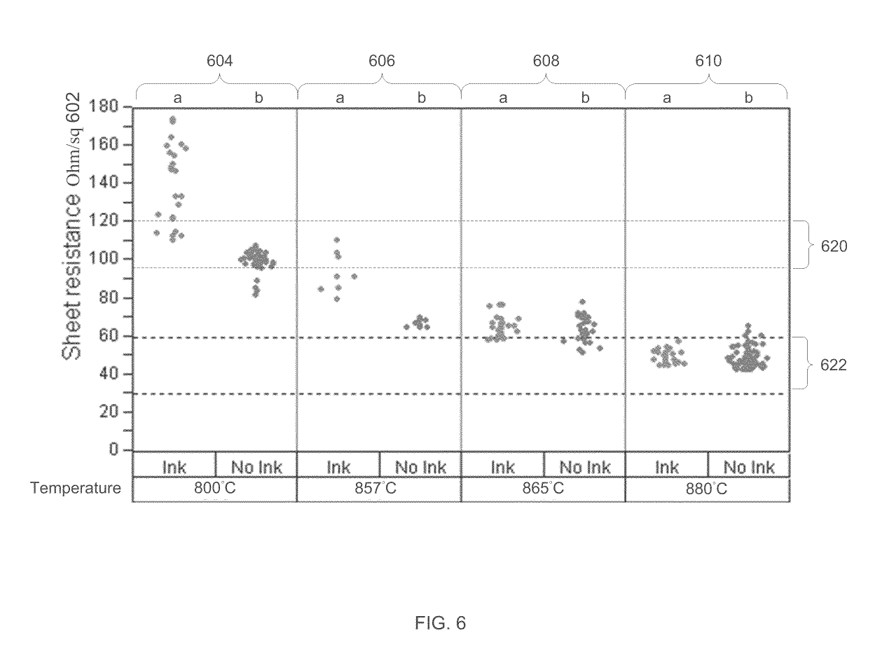

Referring now to FIG. 6, the sheet resistance is compared for four sets of silicon substrates, each configured with a 260 nm doping ink pattern, and processed at various temperatures, in accordance with the invention. Temperature is shown along the horizontal axis, while sheet resistance 602 in Ohm/sq is shown along the vertical axis. As previously mentioned, it is intended that areas under the ink are substantially doped from the ambient dopant source, while the remaining substrate surface area are minimally doped from the ambient dopant source. In these configurations, as the drive-in temperature is increased, the resistivity in the regions printed with ink tends to decrease, which corresponds to a higher dopant concentration. In addition, the inventors believe that the doping ink pattern may be intrinsic or may be doped (for example with phosphorous).

As previously described, sheet resistance range 620 (between about 90 Ohm/sq to about 120 Ohm/sq) corresponds to a lightly doped region optimized for low recombination, while range 622 (between about 30 Ohm/sq and about 60 Ohm/sq) corresponds to a heavily doped region optimized for good ohmic contact.

All substrate sets comprised of saw-damage etched p-type silicon substrates, each with a thickness of about 180 um and a resistivity of about 2 Ohm-cm. The substrates were first cleaned with piranha (a mixture of sulfuric acid (H₂SO₄) and hydrogen peroxide (H₂O₂)). This cleaning was followed by an initial DI water rinsing step, a buffered oxide etch (BOE) dip, a final DI water rinse, and a subsequent N₂ gas drying.

Substrates were then subjected to a baking temperature of 600° C. in a baking ambient in a rapid thermal processing (RTP) tool for a time period of about 3 minutes in order to densify the film and evaporate solvent molecules.

The inventors believe the baking time period may be between about 30 seconds and about 20 minutes. The inventors believe a baking temperature of between about 200° C. and about 600° C. is preferable, a baking temperature of between about 300° C. and about 500° C. is more preferable, and a baking temperature of about 400° C. is most preferable.

Substrate sets 604-610 were then exposed to a liquid 2.5 wt % H₃PO₄ dopant source (ethanol dilution), followed by a dehydration step at about 35° C. for about 3 minutes, and then subjected to a drive-in step on an inline belt furnace, at drive-in temperatures ranging between about 800° C. and about 880° C. for about 20 minutes. The residual PSG glass layers on the substrate surface and the densified film surface were subsequently removed by a BOE cleaning step for about 5 minutes.

In substrate subset 604 with a drive-in temperature of about 800° C., an average sheet resistance of 139.1 ohm/sq was measured in ink areas 604a (i.e., substrate areas underneath the deposited densified nanoparticle film), while an average sheet resistance of 99.3 ohm/sq was measured in non-ink areas 604b (i.e., on a neighboring substrate free of any deposited densified nanoparticle film). That is, the sheet resistance is higher (i.e., lower dopant concentration) in ink areas 604a, which here correspond to the metal contact regions on the solar cell substrate. Consequently, the differential dopant profile between heavily doped and lightly doped regions (as reflected in sheet resistance) is not optimal for the formation of a selective emitter as previously described.

In substrate subset 606 with a drive-in temperature of about 857° C., an average sheet resistance of 93.7 ohm/sq was measured in ink areas 606a, while an average sheet resistance of 67.1 ohm/sq was measured in non-ink areas 606b. That is, although improving, the sheet resistance is still excessively high in ink areas 606a, which correspond to the metal contact regions on the solar cell substrate. Consequently, the differential dopant profile between heavily doped and lightly doped regions (as reflected in sheet resistance) is not optimal for the formation of a selective emitter as previously described.

In substrate subset 608 with a drive-in temperature of about 865° C., an average sheet resistance of 65.0 ohm/sq was measured in ink areas 608a, while an average sheet resistance of 64.2 ohm/sq was measured in non-ink areas 608b. That is, the sheet resistance is high in ink areas 608a, which correspond to the metal contact regions on the solar cell substrate. Consequently, as in substrate subset 604 and substrate subset 606, the differential dopant profile between heavily doped and lightly doped regions (as reflected in sheet resistance) is not optimal for the formation of a selective emitter as previously described.

In contrast, substrate subset 610 shows a partially beneficial differential dopant profile for the formation of a selective emitter. In substrate subset 610a with a drive-in temperature of about 880° C., an average sheet resistance of 49.5 ohm/sq was measured in ink areas 610a, while an average sheet resistance of 48.4 ohm/sq was measured in non-ink areas 610b. Consequently, the differential dopant profile between heavily doped and lightly doped regions (as reflected in sheet resistance) is beneficial, though not optimal, for the formation of a selective emitter as previously described.

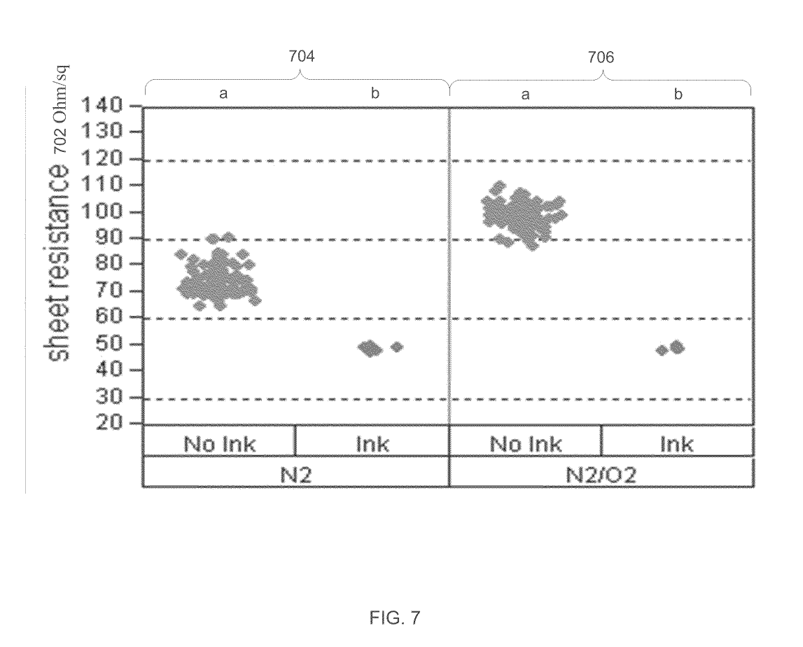

Referring now to FIG. 7, the sheet resistance for two sets of silicon substrates is compared, each processed in a different diffusion ambient with a 3000 nm doping ink pattern and at 800° C., in accordance with the invention. In addition, the inventors believe that the doping ink pattern may be intrinsic or may be doped (for example with phosphorous).

Drive-in ambient (N₂ or N₂/O₂) is shown along the horizontal axis, while sheet resistance 702 in Ohm/sq, is shown along the vertical axis. In this case the inventors demonstrate how for a POCl3 diffusion regime with drive-in performed in an oxidizing ambient the diffusion under dopant-source-limited non-ink areas can be attenuated whereas the diffusion under pseudo-unlimited-dopant-source ink areas is relatively unchanged.

As previously described, a sheet resistance range of between about 90 Ohm/sq to about 120 Ohm/sq corresponds to a lightly doped region optimized for low recombination, while a range of between about 30 Ohm/sq and about 60 Ohm/sq corresponds to a heavily doped region optimized for good ohmic contact.

All substrate sets comprised of saw-damage etched p-type silicon substrates, each with a thickness of about 180 um and a resistivity of about 2 Ohm-cm. The substrates were first cleaned with piranha (a mixture of sulfuric acid (H₂SO₄) and hydrogen peroxide (H₂O₂)). This cleaning was followed by an initial DI water rinsing step, a buffered oxide etch (BOE) dip, a final DI water rinse, and a subsequent N₂ gas drying.

Substrates were then subjected to a baking temperature of about 550° C. and in a baking ambient in a in a quartz tube furnace for a time period of about 12 minutes in order to densify the film and evaporate solvent molecules.

Substrate sets 704-706 were then exposed to a dopant source in a diffusion furnace with an atmosphere of POCl₃, N₂, and O₂, at a deposition temperature of about 800° C. for a deposition time period of about 20 minutes to about 35 minutes, followed by a drive-in temperature of about 900° C. and at a drive-in time period of about 25 minutes. The residual PSG glass layers on the substrate surface and the densified film surface were subsequently removed by a BOE cleaning step for about 5 minutes.

In substrate subset 704, nitrogen (carrier N₂ gas) to oxygen (reactive O₂ gas) ratio of 1.4:1 was used during the initial deposition step followed by a drive-in step with an ambient of principally N₂ gas. The corresponding measured sheet resistance was about 74.2 ohm/sq (mean) in non-ink areas 704a (i.e., substrate areas not covered by a deposited densified nanoparticle film), and a about 48.5 ohm/sq (mean) in ink areas 704b. In contrast, for substrate subset 706, a drive-in ambient ratio of about 50% N₂ gas and 50% O₂ gas was employed, the corresponding measured sheet resistance was about 99.0 ohm/sq (mean) in non-ink areas 706a (i.e., substrate areas not covered by a deposited densified nanoparticle film), and about 48.9 ohm/sq (mean) in ink areas 706b. Consequently, the use of a drive-in ambient that substantially includes an O₂ gas results in lighter diffusion in non-ink areas while leaving the diffusion strength under ink areas relatively unchanged. The authors believe that this approach may also be applied to a phosphoric acid diffusion process.

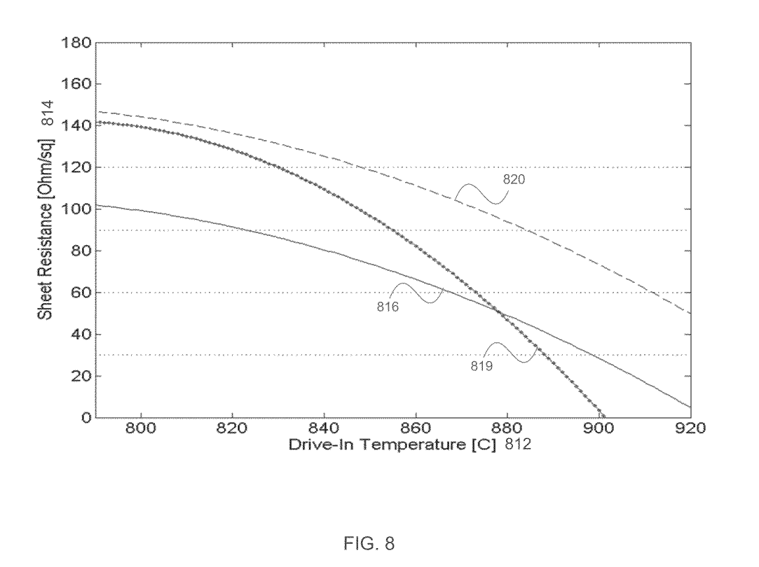

Referring now to FIG. 8, a set of polynomial fitted curves along with one simplified extrapolation curve is shown for FIG. 6, in accordance with the invention. Dopant Drive-in Temperature [° C.] 812 is shown along the horizontal axis, while sheet resistance 814 in Ohm/sq, is shown along the vertical axis.

Plot 819 is a polynomial fitted curve to the sheet resistance versus drive-in temperature data of FIG. 6 for a doping ink subjected to a drive-in in a CDA (approximately 20% O₂) ambient. As can be seen, as the temperature increases a greater amount of dopant is driven in and activated, corresponding to a lower sheet resistance.

Plot 816 is a polynomial fitted curve to the sheet resistance versus drive-in temperature data of FIG. 6 for substrate surface areas not covered with ink processed with a CDA (approximately 20% O₂) ambient, during drive-in.

Plot 820 is the polynomial fitted curve for non-ink areas 816 derived from FIG. 6, but adjusted with an offset that the inventors believe can be achieved by performing a drive-in in an ambient containing at least 50% O₂ gas. This projected offset is based on oxidizing ambient drive-in results achieved in a POCl₃ diffusion regime, as shown in FIG. 7. As can be seen, the increased presence of O₂ gas attenuates the amount of activated dopant in comparison to an ambient of only 20% O₂ gas bringing the non-ink sheet resistance into the ideal range for selective emitter formation. Consequently, the differential dopant profile between heavily doped and lightly doped regions (as reflected in sheet resistance) in the presence of a drive-in ambient that substantially includes an O₂ gas enhances the formation of a selective emitter as previously described.

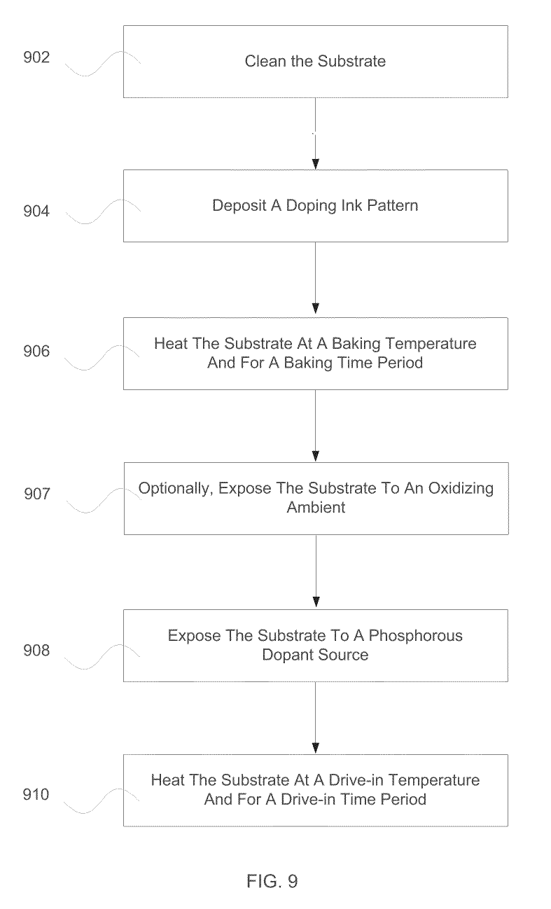

Referring now to FIG. 9, a simplified process is shown for the manufacture of a substrate with a doping ink pattern, in accordance with the invention.

Initially at step 902, the substrate is cleaned by set of substrate cleaning solutions. For example, in a common configuration, the substrate may be initially cleaned with piranha (a mixture of sulfuric acid (H₂SO₄) and hydrogen peroxide (H₂O₂)), followed by an initial DI water rinsing step, a buffered oxide etch (BOE) dip, a final DI water rinse, and subsequent drying in an N₂ gas.

At step 904, a doping enhancing ink pattern is then deposited on the substrate surface. For a doping enhancing effect, a deposited ink thickness (after densification) between about 50 nm and about 2000 nm is preferable, between about 100 nm and about 500 nm is more preferable, 250 nm is most preferable.

At step 906, the substrate is heated at a baking temperature between about 200° C. and about 600° C., more preferably between about 300° C. and about 500° C., and most preferably 400° C., and for a first time period between about 30 seconds and about 20 minutes.

Optionally, at step 907, inventors believe that an oxidation step performed prior to exposing the substrate to a phosphorus dopant source will attenuate the amount of activated dopant under non-ink covered areas in comparison to a non-oxidized surface bringing the non-ink sheet resistance into the ideal range for selective emitter formation. That is, an oxide thickness of about 25 nm to about 30 nm is sufficient to achieve the required level of attenuation. An example of a method for creating such an oxide thickness involves subjecting the substrates to a thermal treatment in a quartz tube furnace in an oxidizing ambient (50% N2 and 50% O₂) at a temperature of 900° C. for a time period of between 60 minutes and 150 minutes.

At step 908, the substrate is exposed to a phosphorous dopant source. In general and as previously described, areas under the ink exposed to a pseudo-unlimited-dopant source, while the remaining substrate surface area is exposed to a limited dopant source.

At step 910, the substrate is heated at a drive-in temperature between about 800° C. and about 950° C., more preferably between about 850° C. and about 900° C., and most preferably 880° C., and for a drive-in period between about 10 minutes and about 60 minutes, more preferably between about 15 minutes and 30 minutes, and most preferably 20 minutes. A drive-in ambient composed of a least 50% O₂ is most preferred.

### Inline Diffusion Apparatus

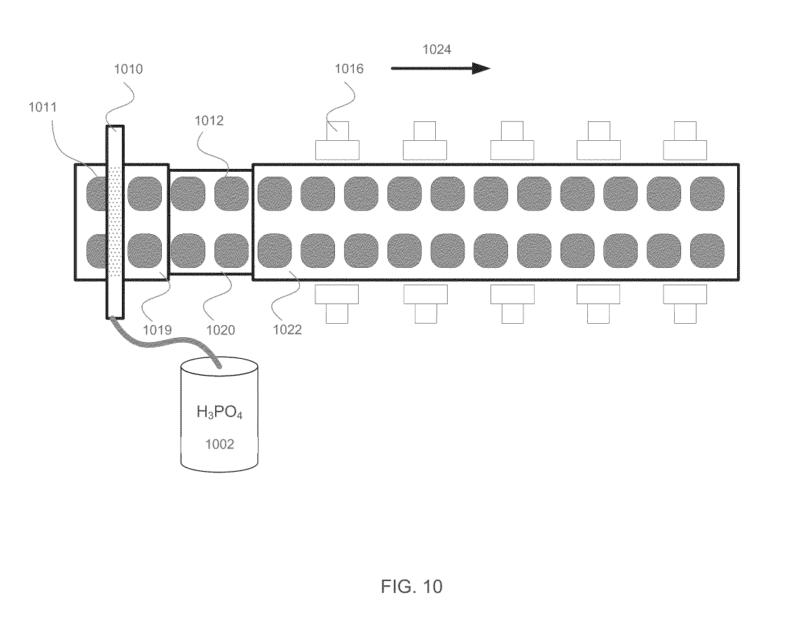

Referring to FIG. 10, a simplified diagram of an inline diffusion apparatus is shown, in accordance with the invention. In general, the inline diffusion furnace applies a dopant source (here a phosphoric acid (H₃PO₄), ethanol mixture) by use of a spray/mist which, in turn after a dehydration step at 35° C., forms a dopant film on the substrate surface, and then heats the substrate for a period of time in order to drive dopant in the dopant source into the substrate to form an emitter.

In this configuration, the simplified diffusion furnace comprises three zones: a deposition zone 1019, a bake zone 1020, and a dopant drive-in zone 1022. Substrates 1012 are generally positioned on a conveyance system (such as a conveyer belt) which move the substrates along direction 1024 through the simplified diffusion furnace. Initially, as substrates enter deposition zone 1019, 2.5 wt % H₃PO₄ 1002 is sprayed on to the substrate surface via sprayer 1010 in order to form a dopant film. Next, the substrates are transported through the bake zone 1020, wherein the substrates may be moderately heated (to about 35° C.) in order to allow solvents in the dopant film to evaporate. The substrates are then further transported through a dopant drive-in zone 1022, generally heated to between about 850° C. to about 950° C. by inline heating elements 1016 wherein the reactions described previously in Equations 1A, 1B, and 2 are propagated, causing phosphorous to be diffused into the silicon substrate.

In a first configuration, the densified nanoparticle ink is configured to impose a partial barrier to the diffusion of phosphorous atoms from H₃PO₄ (via the reaction described in Equation 1A-B). Consequently, exposed substrate areas will tend to absorb a greater amount of dopant than covered areas. In particular, by depositing a negative pattern (i.e. exposed areas will tend to correlate to higher dopant concentrations) at a drive-in temperature above between about 865° C. and about 880° C. for about 20 minutes, and by depositing an ink layer between about 800 nm and about 1200 nm in thickness, a selective (or dual doped) emitter may be formed. That is, both a lightly doped region with sheet resistance of between about 90 Ohm/sq to about 120 Ohm/sq, and a heavily doped region (of the same dopant type) with a sheet resistance of between about 30 Ohm/sq to about 60 Ohm/sq may be formed in a single diffusion step.

For the purposes of this disclosure and unless otherwise specified, “a” or “an” means “one or more.” All patents, applications, references and publications cited herein are incorporated by reference in their entirety to the same extent as if they were individually incorporated by reference.

The invention has been described with reference to various specific and illustrative embodiments. However, it should be understood that many variations and modifications may be made while remaining within the spirit and scope of the invention. Advantages of the invention include the production of low cost and efficient junctions for electrical devices, such as solar cells.

Having disclosed exemplary embodiments and the best mode, modifications and variations may be made to the disclosed embodiments while remaining within the subject and spirit of the invention as defined by the following claims.

What is claimed is:

1. A method of forming a multi-doped junction, comprising:
providing a substrate doped with boron atoms, the substrate comprising a front substrate surface;
depositing an ink on the front substrate surface in a ink pattern, the ink comprising a set of nanoparticles and a set of solvents;
heating the substrate in a baking ambient at a baking temperature and for a baking time period wherein a densified ink layer is formed; and
exposing the substrate to a phosphorous dopant source in a drive-in ambient at a drive-in temperature and for a drive-in time period.

2. The method of claim 1, wherein the phosphorous dopant source includes H₃PO₄.

3. The method of claim 1, wherein the baking time period is between about 30 seconds and about 20 minutes.

4. The method of claim 1, wherein the baking temperature is between about 200° C. and about 600° C.

5. The method of claim 1, wherein the baking temperature is between about 300° C. and about 500° C.

6. The method of claim 1, wherein the baking temperature is about 400° C.

7. The method of claim 1, wherein the drive-in temperature is between about 800° C. and about 950° C. and the drive-in time period is between about 10 minutes and about 60 minutes.

8. The method of claim 1, wherein the drive-in temperature is between about 850° C. and about 900° C. and the drive-in time period is between about 15 minutes and about 30 minutes.

9. The method of claim 1, wherein the drive-in temperature is about 880° C. and the drive-in time period about 20 minutes.

10. The method of claim 1, wherein the ink pattern is a masking ink pattern.

11. The method of claim 10, wherein the densified ink layer is configured with a thickness of between about 50 nm and about 3000 nm.

12. The method of claim 10, wherein the densified ink layer is configured with a thickness of between about 500 nm and about 2000 nm.

13. The method of claim 10, wherein the densified ink layer is configured with a thickness of about 1000 nm.

14. The method of claim 1, wherein the ink pattern is a doping ink pattern.

15. The method of claim 14, wherein the densified ink layer is configured with a thickness of between about 50 nm and about 2000 nm.

16. The method of claim 14, wherein the densified ink layer is configured with a thickness of between about 100 nm and about 500 nm.

17. The method of claim 14, wherein the densified ink layer is configured with a thickness of about 250 nm.

18. The method of claim 14, wherein the drive-in ambient is composed of a least 50% O₂.
